(19) United States
(12) Patent Application Publication
(10) Pub. No.: US 2009/0052148 A1
(43) Pub. Date: Feb. 26, 2009

(54) Structure Of Memory Stick

(76) Inventor: Chin-Tong Liu, Hsinchu City (TW)

Correspondence Address: LIN & ASSOCIATES INTELLECTUAL PROPERTY, INC., P.O. BOX 2339, SARATOGA, CA, 95070-0339, US

(21) Appl. No.: 12/193,047

(22) Filed: Aug. 18, 2008

(30) Foreign Application Priority Data
Aug. 24, 2007 (TW) 096131575

(51) Int. Cl. H05K 5/02

(52) U.S. Cl. 361/752

(57) ABSTRACT

A structure of memory stick is provided, including a substrate case, a bottom case, a circuit board and a cover layer. One end of the circuit board includes a plurality of metal plates surrounded by a plurality of via holes. The circuit board is placed inside the bottom case so that the via holes correspond to the concave trenches of the bottom case. The substrate case covers the top of circuit board with the metal plates exposed. The cover layer is formed to cover the circumference of the engagement part of the substrate case and the bottom case, as well as the surrounding of the metal plates of the circuit board. The cover layer is formed by an inject molding process so that the substrate case, bottom case, circuit board and cover layer all engage together so as to achieve the object of higher assembly stability and waterproof effect.

### FIELD OF THE INVENTION

The present invention generally relates to a structure of memory sticks, and more specifically to a structure of memory sticks with better assembly stability and water-proof effects.

### BACKGROUND OF THE INVENTION

FIG. 1 shows a schematic view of the components of a structure of a conventional memory stick. As shown in FIG. 1, memory stick 10 includes an upper case 101, a lower case 102 and a circuit board 103. The bottom of lower case 102 includes a plurality of screw holes 1021. A plurality of female buckle parts 1022 is formed on the top of circumference stop wall of lower case 102. The size of circuit board 103 is slightly smaller than the bottom surface of lower case 102, and circuit board 103 is placed inside lower case 102. One end of circuit board 103 extends a plurality of metal plates 1031 beyond the circumference stop wall of lower case 102. Metal plates 1031 are located on the surface of a fixed plate 1032. Fixed plate 1032 and metal plates 1031 are all covered with a protection layer 1033. The top of upper case 101 also includes a plurality of screw holes 1011. Screw holes 1011 of upper case 101 are corresponding to screw holes 1021 of lower case 102. A plurality of male buckle parts 1012 is formed on the top of circumference stop wall of upper case 101. Male buckle parts 1021 correspond to female buckle parts 1022, and a fixed trench 1013 is formed on the top of a surface of the circumference stop wall.

After assembly, circuit board 103 is placed inside lower case 102, upper case 101 and lower case 102 are buckled together by male buckle parts 1012 and female buckle parts 1022, a plurality of screws 1014 penetrates screw holes 1011 of upper case 101 and screw holes 1021 of lower case 102 to fasten upper case 101 and lower case 102 to achieve assembly stability. Fixed trench 1013 of upper case 101 can engage protection layer 1033 to the top of the circumference stop wall of lower case 102. In this manner, by fixing protection layer 1033, circuit board 103 is fixed to upper case 101 and lower case 102.

However, as screws 1014 of memory stick 10 may become loose after a long period of use and lead to the loose engagement of upper case 101 and lower case 102 so that liquid may leak in and damage circuit board 103. In addition, when screws 1014 are loose, the fixing of fixed trench 1013 on protection layer 1033 will also become loose, which may lead to the unstable assembly of circuit board 103 to upper case 101 and lower case 102 so that the protection layer 1033 cannot insert into the external main connector. Therefore, the conventional structure of memory stick 10 needs to be enhanced.

### SUMMARY OF THE INVENTION

The present invention has been made to overcome the above-mentioned drawback of conventional structure of flash memory stick. The primary object of the present invention is to provide a novel structure for flash memory stick with higher assembly stability and waterproof effect.

To achieve the above object, the present invention provides a structure of memory stick, including a substrate case, a bottom case, a circuit board and a cover layer, where the bottom of the bottom case forms a flat surface. The boundary of the flat surface forms a boundary stop wall. One end of the flat surface includes a plurality of concave trenches. The flat surface and the boundary stop wall from a housing space for the circuit board. One end of the circuit board includes a plurality of metal plates surrounded by a plurality of via holes. The via holes correspond to the concave trenches of the bottom case. The substrate case covers the top of circuit board and the bottom case. The cover layer is formed to cover the circumference of the engagement part of the substrate case and the bottom case, as well as the surrounding of the metal plates of the circuit board. The cover layer is formed by an inject molding process. During the injection molding process, the material of the cover layer also fills the via holes of the circuit board and the concave trenches of the bottom case so that the substrate case, bottom case, circuit board and cover layer all engage together so as to achieve the object of higher assembly stability and waterproof effect.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

The present invention can be understood in more detail by reading the subsequent detailed description in conjunction with the examples and references made to the accompanying drawings, wherein:

FIG. 1 shows a schematic view of a structure of components of a conventional memory stick;

FIG. 2 shows a schematic view of the structure of memory stick of the present invention;

FIG. 3 shows a dissected view of the components of the memory stick of the present invention;

FIG. 4 shows a schematic view of a partially assembled memory stick of the present invention;

FIG. 5A shows an AA cross-sectional view of FIG. 2;

FIG. 5B shows an BB cross-sectional view of FIG. 2; and

FIG. 5C shows an CC cross-sectional view of FIG. 2.

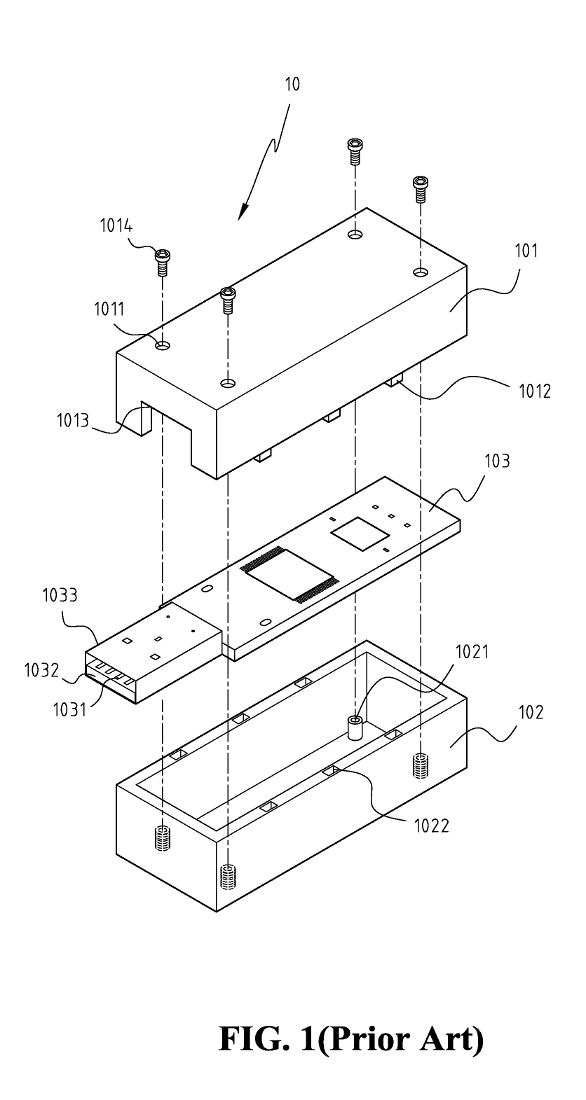

### DETAILED DESCRIPTION OF THE PREFERRED EMBODIMENTS

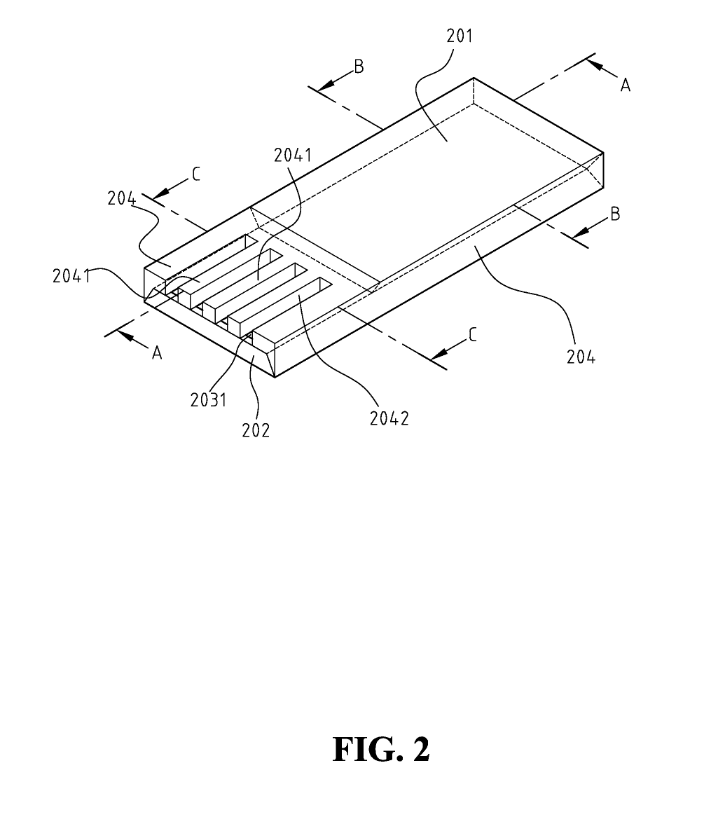

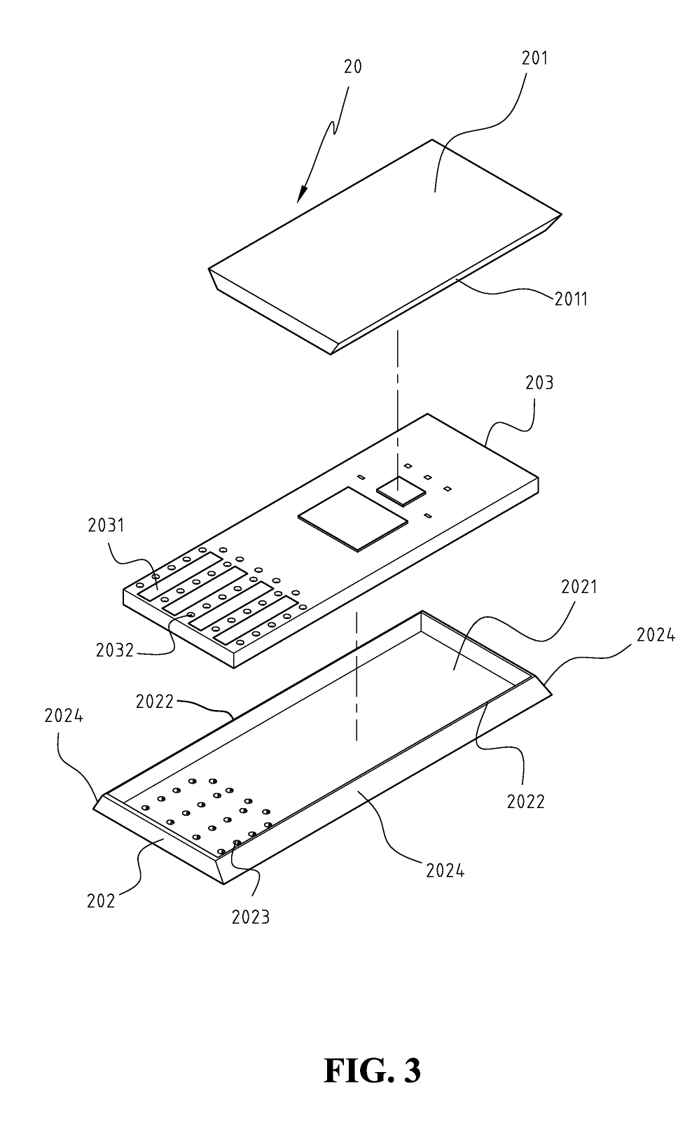

FIGS. 2 and 3 show a three-dimensional view and an dissected view of the memory stick of the present invention. The memory stick 20 of the present invention includes a substrate case 201, a bottom case 202, a circuit board 203 and a cover layer 204, where the bottom of bottom case 202 forms a flat surface 2021. The boundary of flat surface 2021 forms a boundary stop wall 2022. One end of flat surface 2021 includes a plurality of concave trenches 2023. Flat surface 2021 and boundary stop wall 2022 from a housing space for circuit board 203. At least two outer walls of boundary stop wall 2022 are slant surface 2024. In the present embodiment, three outer walls of boundary stop wall 2022 are slant surface 2024, with wide bottom and narrow top. One end of circuit board 203 includes a plurality of metal plates 2031 surrounded by a plurality of via holes 2032. Via holes 2032 correspond to concave trenches 2023 of bottom case 202. Circuit board 203 includes control chips, memory chips and related circuits forming connection to metal plates 2031. Substrate case 201 covers the top of circuit board 203. The length of substrate case 201 is shorter than circuit board 203 so that metal plates 2031 of circuit board 203 are not covered with substrate case 201. At least two sides of the circumference of substrate case 201 are slant surface 2011. In the present embodiment, three sides of the circumference of substrate case 201 are slant surface 2011, with wide top and narrow bottom.

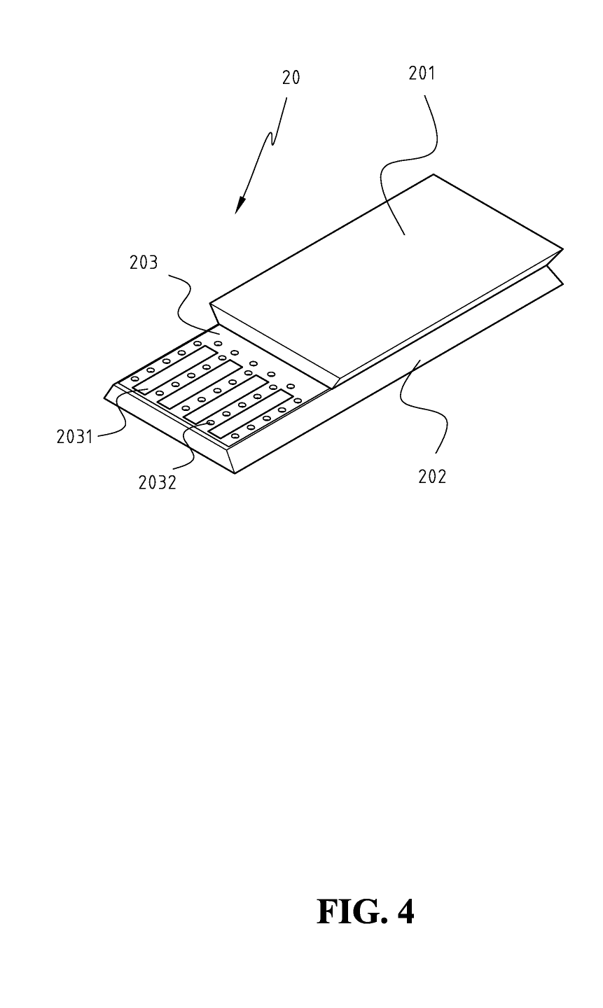

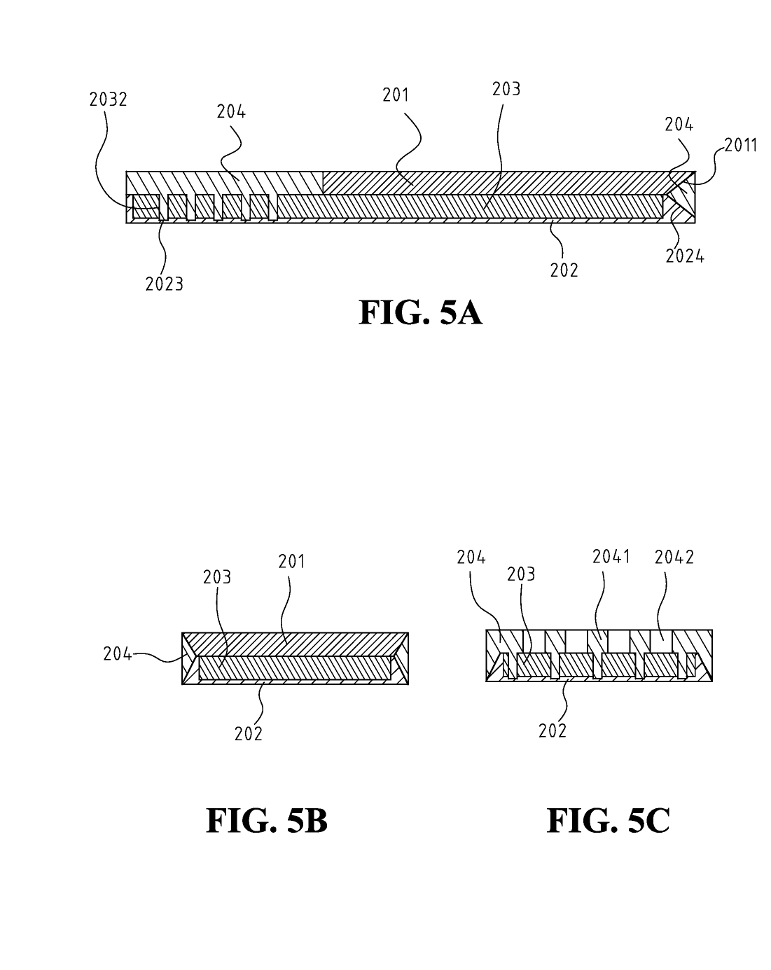

FIG. 4 shows a schematic view of assembly of some components of the present invention. As shown in FIG. 4, when substrate case 201 covers bottom case 202 and circuit board 203, substrate case 201 will not completely shield metal plates 2031 of circuit board 203 because the length of substrate case 201 is shorter. FIG. 2 shows a schematic view of the present invention after assembly. Cover layer 204 is formed to cover the circumference of the engagement part of substrate case 201 and bottom case 202, as well as the surrounding of metal plates 2031 of circuit board 203. Cover layer 204 forms a plurality of ribs 2041 surrounding metal plates 2031, with two neighboring ribs 2041 having a gap 2042. The bottom of gap 2042 is exposed metal plate 2031. As shown in FIGS. 5A-5C, cover layer 204 is formed by an inject molding process to form the shape of the memory stick. During the injection molding process, the material of cover layer 204 also fills via holes 2032 of circuit board 203 and concave trenches 2023 of bottom case 202, as well as the space between slant surface 2011 of substrate case 201 and slant surface 2024 of bottom case 202 so that substrate case 201, bottom case 202, circuit board 203 and cover layer 204 all engage together. In this manner, cover layer 204 can fully prevent the liquid leakage through the engagement part of substrate case 201, bottom case 202 and circuit board 203. Therefore, memory stick 20 of the present invention can achieve the object of higher assembly stability and waterproof effect. The size of the front end of memory stick 20 is the same as the conventional USB connector. Ribs 2041 can further assist the contact of metal plates 2031 and the conductive points inside USB socket to enhance convenience of use.

FIGS. 5A-5C show a cross-sectional view of the present invention. As shown, when substrate case 201 covers the top of circuit board 203 and bottom case 202, substrate case 201 covers only the part of circuit board 203 with control chips and memory chips, while leaving metal plates 2031 exposed. When cover layer 204 is forming with inject molding, the material of cover layer 203 will also fill via holes 2032 of circuit board 203 and concave trenches 2023 of bottom case 202 so that cover layer 204 and bottom case 202 are buckled together. The buckling between cover layer 204 and bottom case 202 enhances the engagement part of the two. Also, cover layer 203 is also formed to surround the circumferences of substrate case 201 and bottom case 202 so that all the components are tightly engaged to achieve the object of assembly stability of the present invention.

In summary, the assembling of the memory stick of the present invention utilizes the cover layer formed by inject molding so that the material of cover layer also fills the via holes of the circuit board and the concave trenches of the bottom case so that the substrate case, bottom case, circuit board and cover layer are all tightly engaged to achieve the objects of higher assembly stability and waterproof effect.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A structure of flash memory stick, comprising:
a bottom case, the bottom of said bottom case forming a flat surface, the boundary of said flat surface forming a boundary stop wall, said flat surface and said boundary stop wall forming a housing space;
a circuit board, placed inside said housing space of said bottom case, one end of said circuit board having a plurality of metal plates surrounded by a plurality of via holes;
a substrate case, covering on top of said circuit board with said metal plates exposed; and
a cover layer, forming on the circumference of the engagement part of said substrate case and said bottom case, and the area surrounding said metal plates.

2. The structure as claimed in claim 1, wherein said cover layer is formed by an inject molding process and the material of said cover layer fills said via holes during inject molding.

3. The structure as claimed in claim 1, wherein said cover layer forms a plurality of ribs in said area surrounding said metal plates, with a gap between two neighboring ribs, and the bottom of said gap is said exposed metal plate.

4. The structure as claimed in claim 1, wherein at least two outer walls of said boundary stop wall are slant surface, and at least two sides of circumference of said substrate case are slant surface, and said material of said cover layer fills the gap between said slant surface of said outer wall of said boundary stop wall and said slant surface of said substrate case.

5. The structure as claimed in claim 1, wherein said flat surface forms a plurality of concave trench on one end.

6. The structure as claimed in claim 5, wherein said via holes of said circuit board correspond to said concave trenches of said bottom case.

7. The structure as claimed in claim 6, wherein said material of said cover layer fills said via holes and said concave trenches in said inject molding process.
